(19) United States
(12) Patent Application Publication
(10) Pub. No.: US 2017/0263984 A1
(43) Pub. Date: Sep. 14, 2017

(54) STORAGE BATTERY EVALUATION DEVICE, STORAGE BATTERY, STORAGE BATTERY EVALUATION METHOD AND NON-TRANSITORY COMPUTER READABLE MEDIUM

(71) Applicant: Kabushiki Kaisha Toshiba, Minato-ku (JP)

(72) Inventors: Yumi FUJITA, Chuo (JP); Tomokazu MORITA, Funabashi (JP); Ena ISHll, Yokohama (JP); Nobukatsu SUGIYAMA, Kawasaki (JP)

(73) Assignee: Kabushiki Kaisha Toshiba, Minato-ku (JP)

(21) Appl. No.: 15/264,931

(22) Filed: Sep. 14, 2016

(30) Foreign Application Priority Data
Mar. 14, 2016 (JP) 2016-050189

(51) Int. Cl. H01M 10/42; G01R 31/36; H01M 10/48

(52) U.S. Cl. CPC H01M 10/425; H01M 10/48; G01R 31/3679; G01R 31/3662; G01R 31/3648; G01R 31/3675; H01M 2010/4278

(57) ABSTRACT

A storage battery evaluation device according to an embodiment of the present invention includes a processor configured to execute a program to provide at least a battery characteristic estimator and a deterioration progress calculator. The battery characteristic estimator estimates a battery characteristic including at least one of battery capacity, internal resistance, and open-circuit voltage of a secondary battery on the basis of data of voltage and current of the secondary battery, the data being measured at the time of charging or discharging of the secondary battery. The deterioration progress calculator calculates a deterioration progress representing the progress of deterioration of the secondary battery, on the basis of a value related to a performance index of the secondary battery, the value being calculated on the basis of the battery characteristic.

### CROSS-REFERENCE TO RELATED APPLICATION(S)

This application is based upon and claims the benefit of priority from Japanese Patent Application No. 2016-050189, filed Mar. 14, 2016; the entire contents of which are incorporated herein by reference.

### FIELD

Embodiments described herein relate generally to a storage battery evaluation device, a storage battery, a storage battery evaluation method and non-transitory computer readable medium.

### BACKGROUND

In recent years, along with the globalization of the economy and corporate activities, even in developing countries, the lifestyle of people has been changed to consume a large amount of energy. Therefore, it is thought that the future energy demand of the world will become very huge. Also in order to maintain the growth of global economy, it is very important to supply energy stably, and hence, it is required for each of the countries to introduce a method to optimize the energy consumption.

As the method to optimize the energy consumption, a smart grid has been attracting attention. The smart grid is a technique that optimizes the supply and demand of electric power by using of techniques, such as IT. In order to practically operate the smart grid, it is important that surplus electric power, generated at the time and place where electric power demand is small, is used at the time and place where electric power demand is large, and thereby, the demand and supply of electric power are balanced across time and place. Therefore, a storage battery, which can store surplus electric power, plays a very important role in the smart grid.

In order to fully promote the smart grid as a national strategy, it is considered that a storage battery needs to be installed in each building which uses electric power. However, when a storage battery is installed in each building, an economic burden on each of general consumers as installers becomes excessively large. Therefore, it is considered that used storage batteries will be more widely used in addition to new storage batteries. However, there may be the case where a used storage battery is replaced immediately after installation since a characteristic of the used storage battery is deteriorated. For this reason, it is necessary to correctly evaluate the value of used storage batteries.

### BRIEF DESCRIPTION OF THE DRAWINGS

FIG. 1 is a block diagram illustrating an example of a schematic configuration of a storage battery evaluation device according to a first embodiment;

FIGS. 2A and 2B are flowcharts of outline processing of the storage battery evaluation device;

FIG. 3 is a view illustrating an example of the history of current and voltage at the time of charging;

FIG. 4 is a flowchart illustrating a process flow of an active material amount calculator;

FIG. 5 is a flowchart illustrating a process flow of an open-circuit voltage calculator;

FIGS. 6A and 6B are views each illustrating an example of a graph (charge amount-OCV curve) representing the relationship between a charged amount and an open-circuit voltage;

FIG. 7 is a view illustrating an example of a graph (SOC-OCV curve) representing the relationship between SOC and the open-circuit voltage;

FIG. 8 is a view illustrating the relationship between SOC and reaction resistance Rct at each temperature;

FIG. 9 is a view for explaining each resistance component;

FIGS. 10A to 10D are views for explaining the progress of deterioration of each performance index;

FIG. 11 is a view for explaining calculation of the amount of electric power (Wh) which can be inputted and outputted;

FIG. 12 is a block diagram illustrating an example of a schematic configuration of a storage battery evaluation device according to a second embodiment;

FIG. 13 is a flowchart illustrating a process flow of a deterioration progress calculation graph processor; and

FIG. 14 is a block diagram illustrating an example of a hardware configuration in an embodiment of the present invention.

### DETAILED DESCRIPTION

Each of embodiments of the present invention calculates a progress of deterioration (referred to as a deterioration progress) of a storage battery, which is used as an index for evaluating the worth of the storage battery.

A storage battery evaluation device according to an embodiment of the present invention includes a processor configured to execute a program to provide at least a battery characteristic estimator and a deterioration progress calculator. The battery characteristic estimator estimates a battery characteristic including at least one of battery capacity, internal resistance, and open-circuit voltage of a secondary battery on the basis of data of voltage and current of the secondary battery, the data being measured at the time of charging or discharging of the secondary battery. The deterioration progress calculator calculates a deterioration progress representing the progress of deterioration of the secondary battery, on the basis of a value related to a performance index of the secondary battery, the value being calculated on the basis of the battery characteristic.

In the following, embodiments according to the present invention will be described with reference to the accompanying drawings. The present invention is not limited to the embodiments.

### First Embodiment

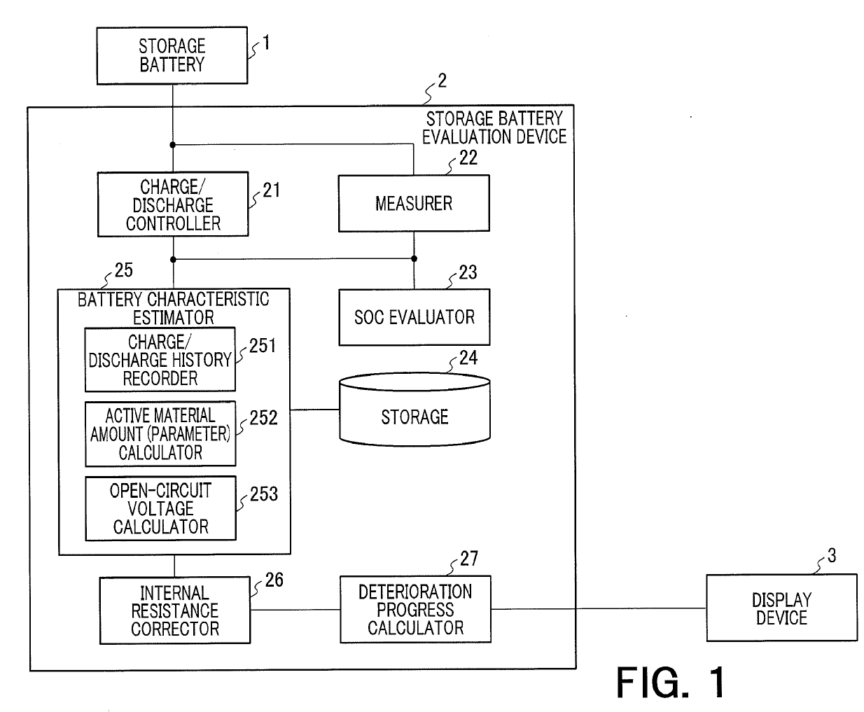

FIG. 1 is a block diagram illustrating an example of a schematic configuration of a storage battery system provided with a storage battery evaluation device according to a first embodiment. The storage battery system includes a storage battery 1, a storage battery evaluation device 2, and a display device 3. The storage battery evaluation device 2 includes a charge/discharge controller 21, a measurer 22, a SOC (State of Charge) estimator 23, storage 24, a battery characteristic estimator 25, an internal resistance corrector 26, and a deterioration progress calculator 27. The battery characteristic estimator 25 includes a charge/discharge history recorder 251, an active material amount (parameter) calculator 252, and an open-circuit voltage calculator 253.

It should be noted that the storage battery evaluation device 2 is realized by a CPU circuit, and the like, and may be provided at the storage battery 1 to be realized as one storage battery 1.

The storage battery 1 is provided with one or more battery packs. Each of the battery packs is provided with one or more battery modules. Each of the battery modules is provided with a plurality of unit cells. The number of battery modules provided in each of the battery packs may be the same or may be different. Further, the number of the unit cells provided in each of the battery modules may be the same or may be different.

The unit cell is assumed to be a secondary battery can be charged and discharged. Here, description is made assuming that the unit cell is a lithium-ion secondary battery.

It should be noted that, in the following description, unless otherwise specified, it is assumed that a storage battery includes battery packs, battery modules, and unit cells.

The storage battery 1 may be, for example, a storage battery which is installed at a fixed location of a building unit, such as, an individual residence, a building, and a factory, or may be a storage battery which is provided for cooperation with a power generation system. Further, the storage battery 1 may also be a storage battery which is interconnected with an electric power system. Further, the storage battery 1 may also be, for example, a storage battery which is provided in a storage battery mounted device, such as an electric bicycle, a drone, and a mobile phone.

It is assumed that the performance of the storage battery 1 is deteriorated as a result of the use of the storage battery 1. Further, the storage battery evaluation device 2 calculates the progress of deterioration of the storage battery 1, as an index to evaluate the value of the storage battery 1. Here, the progress of deterioration of the storage battery 1 is referred to as deterioration progress.

For example, in such a case where a storage battery 1, which is leased or rented, is return at the end of the contract period, or where a purchased storage battery 1 is repurchased as a second-hand battery, it assumes that the storage battery 1 is deteriorated.

When deterioration of the storage battery 1 progressed, the electrical storage capacity, the output electrical power, and the like of the storage battery 1 are lowered. Therefore, there may be a case where the deteriorated storage battery 1 does not meet the specifications required for a facility in which the deteriorated storage battery 1 is to be installed. Therefore, the deterioration progress of the storage battery 1 can be used as an index to determine whether the storage battery 1 can be again leased or rented, or is to be discarded. Further, it can also be considered that the deterioration progress is used as an index to calculate a lease fee or a rental fee. Since the storage battery 1 having small deterioration can be again leased or rented, it is also considered to discount the lease fee or the rental fee of the storage battery 1 on the assumption that the storage battery 1 is properly used. Further, when the storage battery 1 is sold as a used article, the deterioration progress can be used as a reasonable index to determine the sales price. In this way, the deterioration progress can be used as an index to evaluate the value of the storage battery 1.

Further, the deterioration of the storage battery 1 is changed not only by the use frequency or the number of uses, but also by the use environment or an applied load. Therefore, in order to predict the deterioration progress with high accuracy, the storage battery evaluation device 2 does not predict the deterioration progress of the storage battery 1 on the basis of the use frequency or the number of uses of the storage battery 1, but predicts the deterioration progress on the basis of the performance of the storage battery 1.

It should be noted that the storage battery evaluation device 2 estimates the deterioration progress of the storage battery 1 at least before and after the use (before and after lease and rental) of the storage battery 1. Further, the storage battery evaluation device 2 calculates the deterioration progress of the storage battery 1 on the basis of the both estimation results.

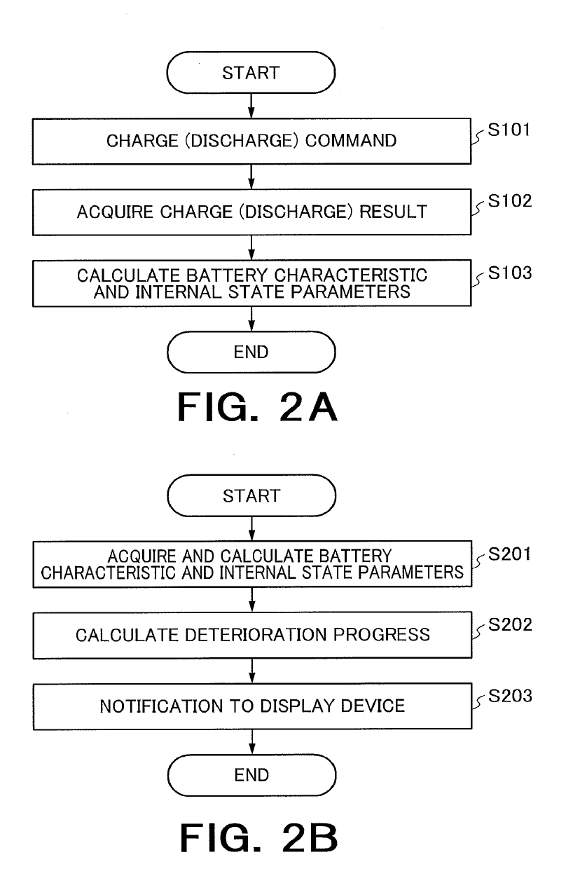

The storage battery evaluation device 2 is connected to the storage battery 1 to measure the state of the storage battery 1. FIGS. 2A and 2B are flowcharts of outline processing of the storage battery evaluation device. FIG. 2A illustrates the processing to grasp the state of the storage battery 1. FIG. 2B illustrates the processing to calculate the deterioration progress of the storage battery 1. It is assumed that these processing flows are performed before and after the lease or rental of the storage battery 1. It should be noted that these processing flows may be performed to allow the use to grasp the deterioration progress of the storage battery 1 in the period of lease or rental.

The processing to estimate the state of the storage battery 1 will be described. The storage battery evaluation device 2 issues an instruction of charge or discharge on a predetermined condition to the storage battery 1 (S101). The storage battery evaluation device 2 acquires the result of charge or discharge from the storage battery 1 (S102), and analyzes the result of charge (S103). The analysis of the result of charge means to calculate characteristics of unit cells (cell characteristics) and the internal state parameters of each of the unit cells, on the basis of the result of charge. Specifically, the amount of active materials of each of the positive and negative electrodes, the internal resistance and the like are estimated on the basis of the data of current and voltage, the data being measured at the time of charge or discharge. Further, the battery capacity and the OCV (Open Circuit Voltage) curve are estimated on the basis of the internal state parameters.

It is assumed that the internal state parameters include the positive electrode capacity (positive electrode mass) of unit cells, the negative electrode capacity (negative electrode mass) of unit cells, the SOC difference, and the internal resistance. The SOC difference means a difference between the initial charge amount of the positive electrode and the initial charge amount of the negative electrode. The battery characteristics are calculated from the internal state parameters such as the battery capacity, the open-circuit voltage and the OCV curve. Further, the internal resistance may be included in the battery characteristics.

The processing to calculate the deterioration progress will be described. The storage battery evaluation device 2 acquires information (present state information) related to the present states of each of the unit cells, such as the voltage and the temperature, from the storage battery 1 (S201). Then, the storage battery evaluation device 2 calculates the deterioration progress, on the basis of previously estimated things: the battery characteristics (cell characteristics), the internal state parameters, and the present state information of each of the unit cells (S202). The storage battery evaluation device 2 notifies the calculated deterioration progress to the display device 3 (S203).

The details of each section and operation of the storage battery evaluation device 2 will be described below.

The display device 3 displays the deterioration progress calculated by the storage battery evaluation device 2. It should be noted that the system configuration described here is an example, and the system configuration of the storage battery evaluation device 2 is not limited to this configuration. For example, the storage battery evaluation device 2 may further include an external device, such as storage, in which the data of deterioration progress is stored as a file. Further, the storage battery evaluation device 2 may be connected to other system and output the deterioration progress to the other system.

Next, each section provided in the storage battery evaluation device 2 will be described.

The charge/discharge controller 21 issues a charge/discharge instruction on a predetermined condition to the storage battery 1. It is necessary to perform the charge and discharge at least before and after the lease and rental of the storage battery 1. Further, the charge/discharge controller 21 may issue the charge/discharge instruction, when receiving the instruction from a user, other system, or the like, via an input device (not illustrated).

The measurer 22 measures information related to the storage battery 1. The measured information includes the voltage between the positive and negative electrode terminals of each of the unit cells, the current flowing into the unit cell, the temperature of the unit cell, and the like.

The SOC estimator 23 estimates the present SOC (State of Charge) of the storage battery 1 from the measurement data of voltage, current, and temperature which are measured by the measurer 22.

The storage 24 stores a function that represents the relationship between the amount of charge and the electric potential of the positive electrode or the negative electrode, each of which configures each electrode of the unit cell.
The storage 24 may store other data.

The battery characteristic estimator 25 estimates the present battery characteristics. The battery characteristics include the battery capacity, the internal resistance, the open-circuit voltage (OCV), and the OCV curve. The OCV curve means a graph which represents the relationship (function) between an index of information about the battery and the open-circuit voltage (OCV). For example, the function may represent the relationship between the open-circuit voltage (OCV) of a secondary battery and the charged state. The function may represent the relationship between OCV and the charged amount of charge of the secondary battery. The function may be a SOC-OCV graph which represents the relationship between SOC and OCV. The function may also be a charged amount-OCV graph which represents the relationship between the charged amount and OCV. The kinds of OCV curves to be calculated may be set beforehand.

A known battery characteristic measurement method can be used for the calculation of the battery characteristics. Specifically, electrochemical measurement methods may be used such as a charge-discharge test in which the battery capacity is measured by actually supplying a current, a current rest method in which the internal resistance value is mainly measured, and an AC impedance measurement. Further, combinations of these methods may be used. Further, a method may be used, in which battery characteristics are estimated in a simplified manner by analysis of the charge-discharge curve.

The internal configuration of the battery characteristic estimator 25 will be described.

The charge/discharge history recorder 251 stores data (history) of voltage, current, temperature, and the like, measured by the measurer 22 at the time of charge or discharge of the storage battery 1. The recording is repeatedly performed every predetermined time interval during the period from the start to the end of charging of the storage battery 1. This time interval may be set freely according to the process using the recorded data. For example, it is considered that the time interval is set between about 0.1 second and about 1 second. The time of the recording data may be an absolute time or may be a relative time from when the charging is started. Further, when the process of the charge/discharge history recorder 251 is repeated at fixed time intervals, the recording of time may be omitted.

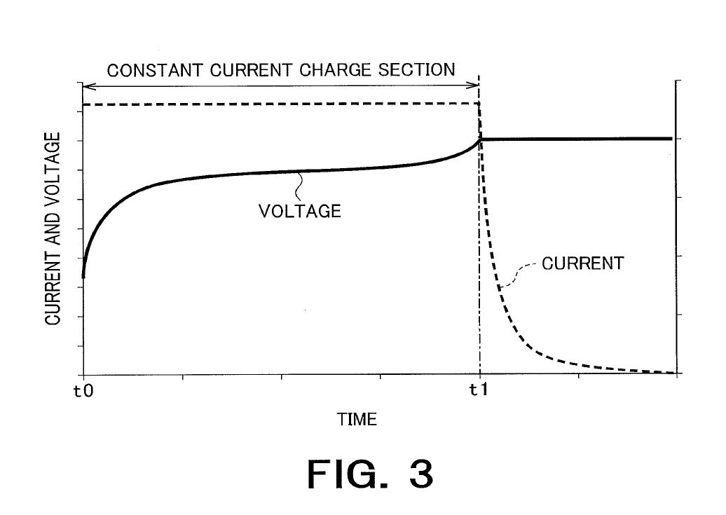

FIG. 3 is a view illustrating an example of current and voltage data at the time of charging. The data illustrated in FIG. 3 represent an example of a constant current-constant voltage charging method which is generally used as a charging method of a secondary battery. In FIG. 3, the broken line represents the current history, and the solid line represents the voltage history.

In the process of the active material amount calculator 252 described below, for example, the whole of the charge history of constant current-constant voltage charging may be used, and a charge history of constant current-constant voltage charging in a in a part of section (for example, between t0 and t1 in FIG. 3) may also be used.

On the basis of the history recorded by the charge/discharge history recorder 251, the active material amount calculator 252 respectively calculates the amount of active materials which configure the positive electrode or the negative electrode of each of the unit cells, the initial charge amount, and the internal resistance of each of the unit cells.

The active material amount calculator 252 uses a function to calculate the battery voltage on the basis of the amount of active materials and the internal resistance. The amount of active materials and the internal resistance are obtained by regression calculation, to reduce the difference between measured voltage and calculated voltage of the battery on the basis of the current data and the voltage data at the time of charge or discharge of the battery, and on the basis of the function. It should be noted that an example of the case where the positive electrode is configured by a plurality of active materials is shown in Patent Literature 3, but in the present embodiment, an example of a secondary battery, in which each of the positive electrode and the negative electrode is formed of one kind of active material, is described.

When a secondary battery, in which each of the positive electrode and the negative electrode is formed of one kind of active material, is charged, the terminal voltage Vt at time t can be expressed by the following expression.

$$\begin{matrix}[ Expression 1 ] & \\ {V}_{t} = {f}_{c} ( {q}_{0}^{c} + \frac{{q}_{t}}{{M}_{c}} ) - {f}_{a} ( {q}_{0}^{a} + \frac{{q}_{t}}{{M}_{a}} ) + {RI}_{t} & ( 1 )\end{matrix}$$

In the expression, Iₜ represents the current value at time t, and qₜ represents the charge amount of the battery at time t. Further, f_{c} is a function representing the relationship between the charge amount and the electric potential of the positive electrode, and fₐ is a function representing the relationship between the charged amount and the electric potential of the negative electrode. Further, qₒ^{c} represents the initial charge amount of the positive electrode, and M_{c} represents the mass of the positive electrode. Further, qₒ^{a} represents the initial charge amount of the negative electrode, and Mₐ represents the mass of the negative electrode, and R represents the internal resistance.

The current data recorded by the charge/discharge history recorder 251 can be used as the current value Iₜ. The charged amount qₜ is calculated by time integration of the current value Iₜ. Each of the function f_{c} and the function fₐ is recorded, as function information, in the storage 24.

Other five values (parameter set) of the positive electrode initial charge amount qₒ^{c}, the positive electrode mass M_{c}, the negative electrode initial charge amount qₒ^{a}, the negative electrode mass Mₐ, and the internal resistance R are estimated by regression calculation.

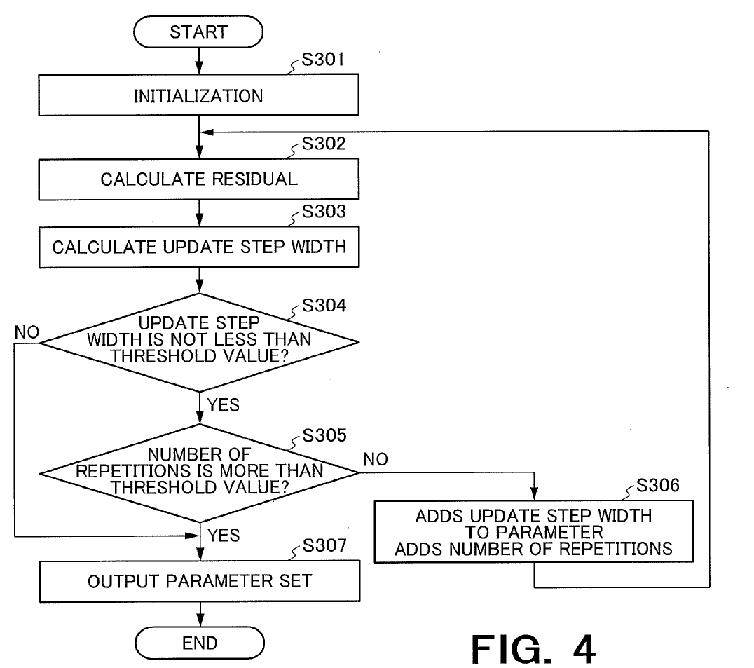

FIG. 4 is a flowchart illustrating a process flow of the active material amount calculator 252. The process of the active material amount calculator 252 is started after the charging of the storage battery 1 is completed.

The active material amount calculator 252 performs initialization, and then sets initial values to the parameters described above, and sets the number of repetitions of regression calculation to 0 (S301). As the initial value, for example, a value calculated when the active material amount calculation process was performed at the previous time, or an assumed value may be used.

The active material amount calculator 252 calculates the residual E represented by the following expression (S302).

$$\begin{matrix}[ Expression 2 ] & \\ \begin{matrix}E = {\sum }_{t = 0}^{{t}_{end}} {( {V}_{bat \_ t} - {V}_{t} )}^{2} \\ = {\sum }_{t = 0}^{{t}_{end}} {( {V}_{bat \_ t} - ( {f}_{c} ( {q}_{0}^{c} + \frac{{q}_{t}}{{M}_{c}} ) - {f}_{a} ( {q}_{0}^{a} + \frac{{q}_{t}}{{M}_{a}} ) + {RI}_{t} ) )}^{2}\end{matrix} & ( 2 )\end{matrix}$$

In the expression, V_{bat}_{_}ₜ represents the terminal voltage at time t, and t_{end} represents the charging end time.

The active material amount calculator 252 calculates the update step width of the parameter set (S303). The update step width of the parameter set can be calculated by using, for example, the Gauss-Newton method, the Levenberg-Marquardt method, or the like.

The active material amount calculator 252 determines whether or not the magnitude of the update step width is less than a predetermined magnitude (S304). When determining that the magnitude of the update step width is less than the predetermined magnitude (NO in S304), the active material amount calculator 252 determines that the calculation has converged, and outputs the present parameter set (S307). When determining that the magnitude of the update step width is not less than the predetermined threshold (YES in S304), the active material amount calculator 252 confirms whether or not the number of repetitions of the regression calculation exceeds a predetermined value (S305).

When determining that the number of repetitions of the regression calculation is more than the predetermined value (YES in S305), the active material amount calculator 252 outputs the present parameter set (S307). When determining that the number of repetitions of the regression calculation is not more than the predetermined value (NO in S305), the active material amount calculator 252 adds the update step width calculated in S303 to the parameter set, and adds one to the number of repetitions of the regression calculation (S306). Further, the active material amount calculator 252 again returns to the calculation of the residual again (S302). The above is the flowchart which illustrates the process flow of the active material amount calculator 252.

In the present embodiment, the charge history is used as the input of the active material amount calculator 252, but even when the discharge history is used, the amount of the active material can be similarly calculated. It is possible that the process flow and the parameters used by the active material amount calculator 252 where the discharge history is used may be the same as those where the discharge history is used.

The open-circuit voltage calculator 253 calculates the open-circuit voltage. Further, the open-circuit voltage calculator 253 calculates the relationship between the battery charge amount and the open-circuit voltage by using the initial charge amount qₒ^{c} of the positive electrode, the positive electrode mass M_{c}, the initial charge amount qₒ^{a} of the negative electrode, and the negative electrode mass Mₐ, which are calculated by the active material amount calculator 252.

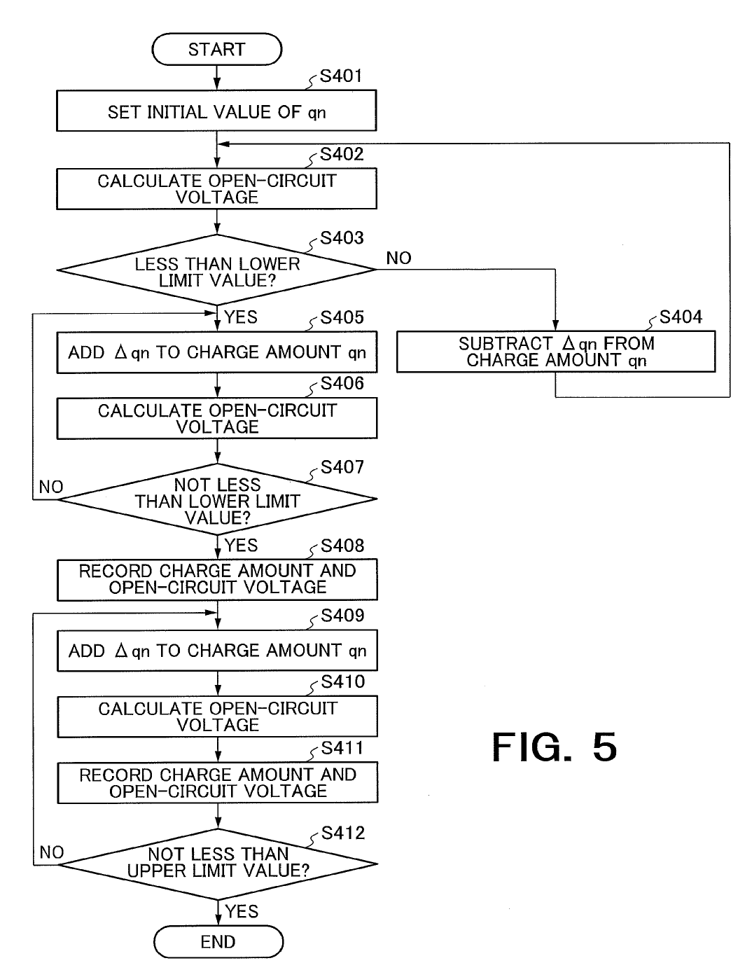

FIG. 5 is a flowchart which illustrates the process flow of the open-circuit voltage calculator 253. The flowchart is started after the process of the active material amount calculator 252 is ended. The process of the flowchart is as follows. The charge amount qn is repeatedly increased or decreased by a fixed value Δqn. Thereby, a charge amount qn0 is found. The charge amount qn0 is the charge amount qn when the open-circuit voltage less than a lower limit value becomes not less than the lower limit value. The found qn0 is then set as an initial value, and the charge amount qn is repeatedly increased by Δqn until the open-circuit voltage exceeds an upper limit value, while the charge amount and the open-circuit voltage are recorded each time when the charge amount is increased. Thereby, the relationship between the charge amount and the open-circuit voltage can be calculated in the range from the lower limit value to the upper limit value of the open-circuit voltage.

The open-circuit voltage calculator 253 sets the initial value of the charged amount qn (S401). The initial value of qn may be set to 0 or a value smaller than 0 by several percent of the nominal capacity of the storage battery 1. Specifically, when the nominal capacity of the storage battery 1 is 1000 mAh, the initial value of qn may be set in the range of about −50 mAh to about 0 mAh.

The open-circuit voltage calculator 253 calculates the open-circuit voltage (S402).
In the calculation of the open-circuit voltage, the following expression can be used.

$$\begin{matrix}[ Expression 3 ] & \\ {E}_{n} = {f}_{c} ( {q}_{0}^{c} + \frac{{q}_{n}}{{M}_{c}} ) - {f}_{a} ( {q}_{0}^{a} + \frac{{q}_{n}}{{M}_{a}} ) & ( 3 )\end{matrix}$$

Next, the open-circuit voltage calculator 253 compares the calculated open-circuit voltage with the predetermined lower limit voltage (S403). The lower limit voltage is a value determined by the combination of the positive electrode active material and the negative electrode active material used in the storage battery 1.
Specifically, for each of the positive electrode active material and the negative electrode active material, each voltage is determined in each of the use range which is suitable for each of viewpoints such as safety, battery life and resistance. On the basis of combinations of those voltages, the lower and upper limit voltages in the use range of the battery are determined.

When the open-circuit voltage is not less than the predetermined lower limit voltage (NO in S403), the open-circuit voltage calculator 253 subtracts Δqn from the charged amount qn (S404), and calculates the open-circuit voltage again (S402). When the open-circuit voltage is less than the predetermined lower limit voltage (YES in S403), the open-circuit voltage calculator 253 adds the Δqn to the charged amount qn (S405). Thereby, the charged amount qn approaches the lower limit value. The value of Δqn can be set to a value freely. For example, it is considered that Δqn is set to a value in the range from about 1/1000 to about 1/100 of the nominal capacity of the storage battery 1. Specifically, it is considered that, when the nominal capacity of the storage battery 1 is 1000 mAh, Δqn is set to a value in the range from about 1 mAh to about 10 mAh.

The open-circuit voltage calculator 253 calculates the open-circuit voltage by using the added charged amount qn+Δqn (S406). Then, the open-circuit voltage calculator 253 compares the calculated open-circuit voltage with the lower limit voltage described above (S407). When the open-circuit voltage is less than the lower limit voltage (NO in S407), the open-circuit voltage calculator 253 returns to S405, and again, adds Δqn to the charged amount qn (S405). When the open-circuit voltage is not less than the lower limit voltage (YES in S407), the open-circuit voltage less than the lower limit value becomes not less than the lower limit value, and hence, the open-circuit voltage calculator 253 sets the charged amount qn at this time as qn0, and records the charged amount qn0 together with the open-circuit voltage En (S408). It should be noted that the value of the charged amount qn0 may be set to 0 as the reference value. In this case, the value, obtained by subtracting qn0 from the value of the charge amount qn, is recorded in recording.

The open-circuit voltage calculator 253 adds Δqn to the charged amount qn (S409), and calculates the open-circuit voltage (S410). Then, the open-circuit voltage calculator 253 records the value obtained by subtracting qn0 from the charge amount qn, and the calculated open-circuit voltage En (S411).

The open-circuit voltage calculator 253 compares the computed open-circuit voltage with the predetermined upper limit voltage of the battery (S412). The upper limit voltage of the battery is a value determined by combination of the positive electrode active material and the negative electrode active material in the storage battery 1. When the open-circuit voltage is less than the predetermined upper limit voltage (NO in S412), the open-circuit voltage calculator 253 adds Δqn to the charge amount qn again (S409). When the open-circuit voltage is not less than the predetermined upper limit voltage (YES in S412), the open-circuit voltage calculator 253 ends the process. The above is the flowchart which illustrates the process flow of the open-circuit voltage calculator 253.

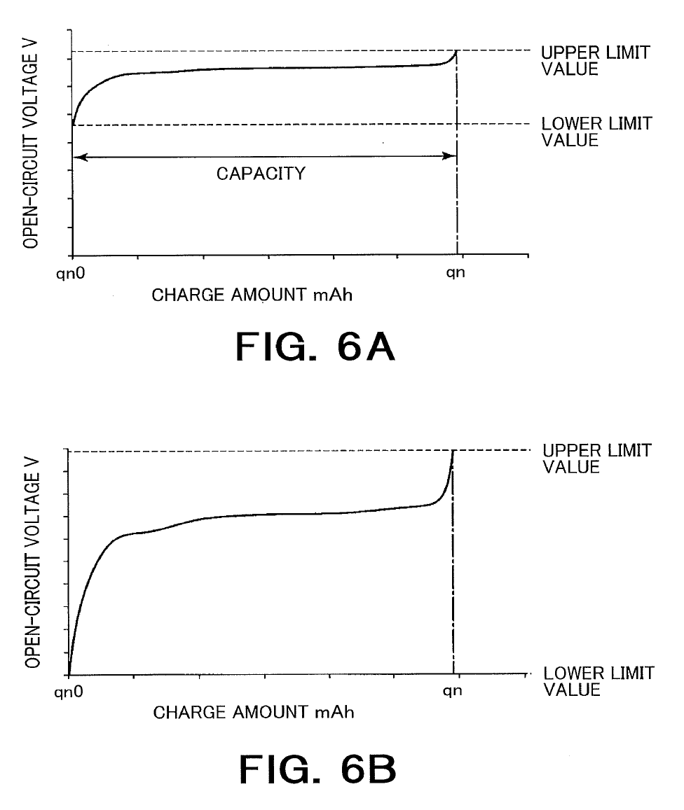

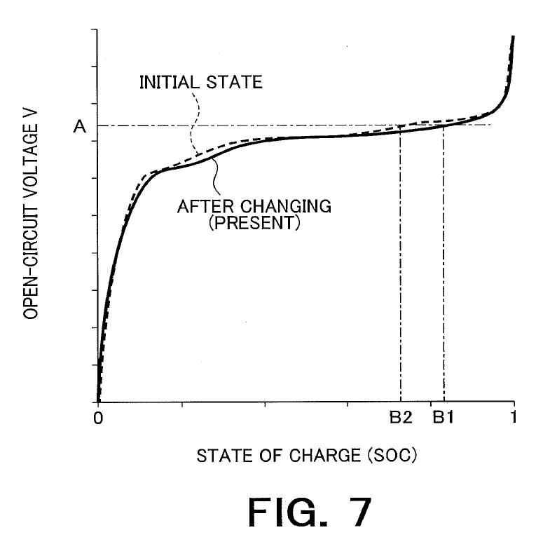

FIGS. 6A and 6B are views each illustrating an example of a graph (charge amount-OCV curve) representing the relationship between a charged amount and an open-circuit voltage. FIG. 6(A) illustrates the charge amount-OCV curve in the current state obtained by the open-circuit voltage calculator 253. FIG. 6(B) is a view in which the vertical axis of the graph illustrated in FIG. 6(A) is within the range from the lower limit voltage to the upper limit voltage. FIG. 7 is a view illustrating an example of a graph (SOC-OCV curve) which represents the relationship between SOC (State of Charge) and the open-circuit voltage. FIG. 7 is different from FIG. 6 in which the horizontal axis is not the charge amount but the SOC. In FIG. 7, the graph (solid line) obtained by converting the graph illustrated in FIG. 6(B) to the SOC-OCV curve, and the graph (broken line) of the SOC-OCV curve of the battery in the initial state are illustrated in an overlapped state. The broken line in FIG. 7 represents the open-circuit voltage of the battery in the initial state. The solid line in FIG. 7 represents the open-circuit voltage of the battery in the current state after the deterioration of the battery. The SOC illustrates the ratio of the amount of charge currently charged, with respect to the full charge capacity, and is represented by a value of 0 to 1, or a value of 0 to 100%.

It should be noted that, in the description here, the state simply referred to as the charging state includes the charge amount and the like in addition to the SOC.

In the curve after the change, the length of the curve is shortened according to the decrease of the capacity. Further, according to FIG. 7, it can be seen that not only the length of the curve but also the shape of the curve are changed. For example, in the case where the charging state (SOC) is estimated on the basis of the open-circuit voltage, when the measured open-circuit voltage is A, the correct charging state (current charging state) is B1. However, when it is considered that the curve in the graph of the open-circuit voltage is not changed. That is assumed that the open-circuit voltage is obtained by the SOC-OCV curve in the initial state, the charging state at the voltage A can be obtained as B2, and hence, the estimation accuracy of the charging state is lowered. Therefore, as in the first embodiment, when the SOC-OCV curve in the current state is used, the charging state can be measured with high accuracy.

Therefore, according to the first embodiment, the relationship (charge amount-OCV curve or SOC-OCV curve) between the charge amount changed according to the use of the battery and the open-circuit voltage can be accurately grasped without specially performing charging and discharging, or the like, as a result of which the charging state can be accurately estimated.

It should be noted that here, a case is described where each of the positive electrode and the negative electrode of the secondary battery is formed of one type of active material, but the first embodiment can be also applied similarly to a secondary battery in which the positive electrode or the negative electrode is formed of a plurality of active materials. Further, when the storage, in which the amount of the active material of the storage battery 1 is stored, is prepared beforehand, the open-circuit voltage calculator 253 can calculate a graph representing the relationship between the charge amount and the open-circuit voltage in the predetermined voltage range of the secondary battery by using the amount of the active material stored in the storage.

The internal resistance corrector 26 corrects the internal resistance at the current temperature T of the storage battery 1 on the basis of the internal resistance R calculated by the battery characteristic estimator 25, and on the basis of the temperature T detected by the measurer 22. The corrected internal resistance by the internal resistance corrector 26 is referred to as the internal resistance Rcr.

The correction of the internal resistance based on temperature is performed by the internal resistance corrector 26, will be described.

The correction of the internal resistance based on temperature provides, for example, means to correct the influence of temperature from a result of a battery characteristics diagnosis method, and to expand a temperature range where the battery characteristics diagnosis method can be preferably applied, a battery characteristics diagnosis method in which the battery capacity, the internal resistance, and the degree of degradation of each of the active materials of each of the positive and negative electrodes are estimated from the charge and discharge curve by reference to the charge amount-OCV data of each of the active materials.

The principle and method for the correction of temperature will be described. A lithium ion secondary battery includes the positive and negative electrodes opposite to each other, and an electrolyte including Li salt between the positive and negative electrodes. Further, the active material is applied on a current collection foil in each of the positive electrode and the negative electrode. The current collection foils are respectively connected to positive and negative electrode terminals of an outer casing of the battery. At the time of charge and discharge of the battery, the Li ions move between the positive electrode active material and the negative electrode active material through the electrolyte, and thereby electrons flow the active materials into the external terminals.

Each of the active materials includes the amount of Li reversibly inserted or detachable, and electric potential. The amount of energy, which the battery can store in a range of fixed charge and discharge voltage, is determined by the amount and the combination of the positive electrode active material and the negative electrode active material in the battery.

Further, at the time of charge and discharge, there are caused Li ion conduction, charge transfer resistance due to Li ions in the electrolyte penetrating into the active material, resistance of a film formed on the interface between the electrolyte and the active material, and electrical resistance due to electrons flowing through the active material and the current collection foil. The internal resistance of the battery is the sum total of the Li ion transfer resistance, the electron transfer resistance, the charge transfer resistance, the film resistance, and the diffused resistor in the positive electrode and the negative electrode.

Generally, in a battery control system in a lithium ion secondary battery, the voltage of each of the unit cells, the temperature in the battery pack, and the like, are measured in the viewpoint of safety. When the battery performance can be calculated on the basis of the measured data, the deterioration diagnosis can be performed without cost and time.

However, it is very difficult to analyze the behavior of the actually used battery whose charging and discharging conditions are changed minutely randomly. The behavior of the actually used battery generates phenomena, in which the time-dependent resistance, the diffusion resistance, the relaxation process, and the like, are complicatedly combined, cannot be easily modelled to calculate. On the other hand, when only simple behavior, such as, for example, behavior in charging an electric vehicle under fixed conditions, is targeted as the object of analysis, the behavior can be analyzed by a simplified model.

Therefore, in a battery performance estimation method according to the present embodiment, values of variables are determined by fitting calculation using, as variables, the amount of each of the active materials, the rise (overvoltage) of the battery voltage due to internal resistance at application of charge current, on the basis of an “electric potential-charge amount” curve associated with the Li insertion-elimination reaction of each active material, which is obtained by data (charge-discharge curve) of charge or discharge under fixed conditions. Thereby, it is possible to estimate the capacity reduction (reduction of each active material) and the increase in internal resistance.

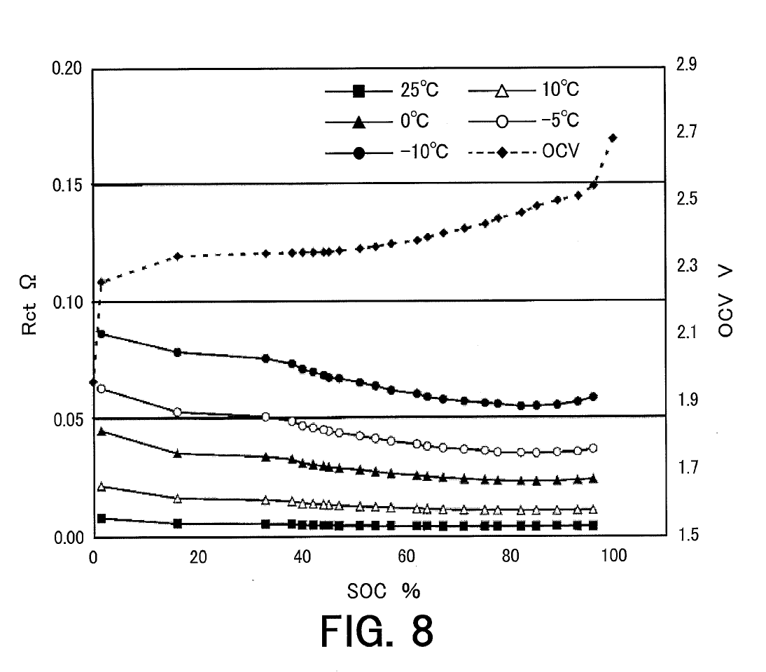

However, under actual use conditions of a battery, the temperature conditions are changed according to the outside environment, the state of the battery at the time of charging, and the like. When the temperature of the battery is changed, battery performance is also changed. Especially, the internal resistance is greatly increased by decrease of temperature. FIG. 8 is a view illustrating the relationship between the SOC and the reaction resistance Rct at each temperature. The reaction resistance Rct is one of the internal resistance components. As illustrated in FIG. 8, it can be seen that the reaction resistance is greatly changed due to the difference in temperature. For this reason, even when the analysis results of measurement data at different temperatures are compared with each other, the change of the analysis result is greatly influenced by the temperature, and hence, it is difficult to evaluate the increase in the internal resistance by degradation.

Therefore, in order to evaluate the progress of deterioration and to estimate the battery characteristics on the basis of the measurement data of the battery under actual use, it is necessary to perform temperature correction of the internal resistance.

The internal resistance of a battery is compounded by a plurality of kinds of resistance components. Each of the resistance components has a different increase rate based on the temperature dependence and the deterioration. For this reason, the proportion of resistance is changed by the progress of deterioration, and thereby, the temperature dependence of the internal resistance as a whole is changed. By paying attention to this fact, the temperature correction of internal resistance in the battery performance estimation method of the present embodiment is performed as follows. The internal resistance is divided into three components of the reaction resistance Rct, the diffusion resistance Rd, and the ohmic resistance Rohm. Each of the components is corrected to the value at the reference temperature T0 according to the temperature dependence specific to each of the components. Then, the corrected components are summed.

Specifically, the internal resistance at temperature at the time of measurement is corrected to that at the reference temperature by using the following expressions. It should be noted that Rgas in the following expression represents a gas constant. Further, T0 represents the reference temperature, T represents the battery temperature at the time of measurement, and R1 represents a constant. Each of Ea, Eb, and Ec represents a constant used for determining the temperature dependence of each of the resistance components.

(Reaction Resistance)

Rct(T0)=Rct(T)×Exp(−Ea/(Rgas·T))/Exp(−Ea/(Rgas·T0))

(Diffusion Resistance)

Rd(T0)=Rd(T)×Exp(−Eb/(Rgas·T))/Exp(−Eb/(Rgas·T0))

(Ohmic Resistance)

Rohm(T0)=(Rohm(T)−R1)×Exp(−Ec/(Rgas·T))/Exp(−Ec/(Rgas·T0))+R1

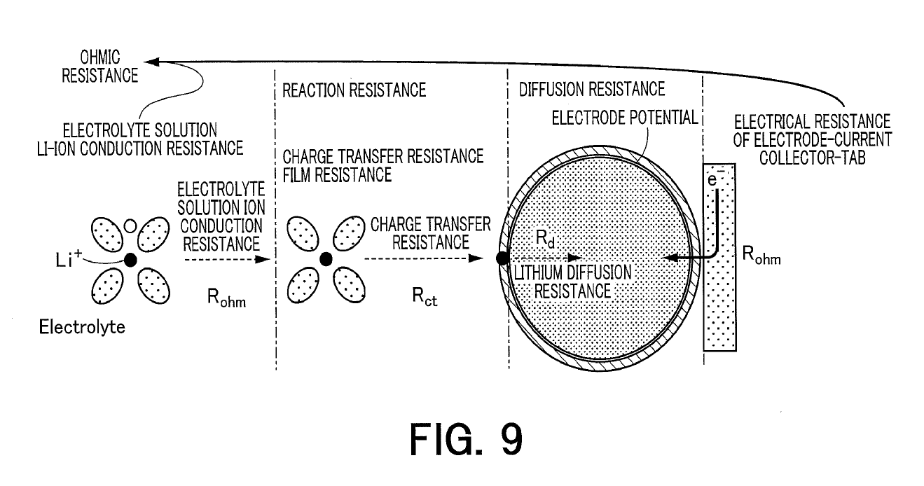

FIG. 9 is a view which explains each of the resistance components. The ohmic resistance includes the ionic conduction resistance of the electrolyte solution, and the electron conduction resistance in the battery. The electron conduction resistance having relatively small temperature dependence is set to a constant. The reaction resistance includes the charge transfer resistance and the film surface resistance. The diffusion resistance includes the resistance accompanying lithium ion diffusion in the active material and the electrodes.

The ohmic resistance Ec represents activation energy due to the movement of Li ions in the electrolyte solution. The reaction resistance Ea represents energy when Li ions, which are solvated in the electrolyte solution, are desolvated on the surface of the active material surface. The diffusion resistance Eb is considered to be activation energy caused by the movement between Li ion sites in the active material. Therefore, it can be considered that these values are at constant and are not changed in the deterioration process.

The values of Ea, Eb and Ec can be calculated by the AC impedance measurement, the current pulse measurement, and the like, of a unit cell. The values of Ea, Eb and Ec, which are related to the battery to be analyzed, may be calculated from the previously measured values, and stored in the storage 24. Then, the stored values of Ea, Eb and Ec may be referred to at the time of the temperature correction calculation of the internal resistance.

Next, there will be described a method in which the internal resistance is calculated by the three divided components thereof when the battery characteristics are estimated from a charge and discharge curve.

Each of the three components of the internal resistance is increased in the deterioration process of the battery, but the rate of increase due to the deterioration is different for each of the components. Therefore, when the range of the battery life to be evaluated is limited, it may be assumed that the deterioration is not caused. For example, when it was assumed that the lower limit of evaluation is about 90% to about 70% of the remaining capacity in a battery of an electric vehicle, some of the resistance components might be approximated to be constant in the battery life, although the some of the resistance components are influenced by the use conditions, the configuration of the battery, and the like.

(First Method)

The first method, in which the three components are calculated from the calculated internal resistance value of the battery, is a method in which the ohmic resistance component and the diffusion resistance component are regarded as constants, and the residual is regarded as the reaction resistance. In this method, it is assumed that the ohmic resistance component and the diffusion resistance component are not increased due to deterioration, and also, it is considered that only temperature change is dependent on the cell temperature. In the analysis of the charge and discharge curve, the ohmic resistance component and the diffusion resistance component at the temperature T are subtracted from the internal resistance value estimated at the temperature T, and the remaining value is set as the reaction resistance component. Then, the respective components are corrected to the value at the reference temperature T0 and are summed to calculate the internal resistance value at the reference temperature T0. The first method is applied to the case where the battery is gently used under such conditions that the SOC is within the range in which the active materials of the positive and negative electrodes are stable, that the temperature is close to the room temperature or less than the room temperature, and that the battery current is relatively small.

(Second Method)

The second method is a method in which each of the ohmic resistance component and the diffusion resistance component is estimated by a function based on the relationship between each of the two resistance components and the cumulative time or the cumulative electric power amount, and the residual is set as the reaction resistance. In this method, the ohmic resistance component and the diffusion resistance component are calculated on the assumption that the degradation of each of the ohmic resistance component and the diffusion resistance component are correlated with the time or the charge-discharge cycle amount. In the analysis of the charge and discharge curve, the ohmic resistance component and the diffusion resistance component, which are calculated, are subtracted from the internal resistance estimated at the temperature T, and the residual is set as the reaction resistance. Then, the respective components are corrected to the value at the reference temperature T0 and are summed to calculate the internal resistance value at the reference temperature T0. The second method is suitable for the case where the degradation of each of the ohmic resistance component and the diffusion resistance component is relatively small but surely progresses.

Further, it may be determined to use the cumulative time and or cumulative electric power amount according to the use environment. For example, the degradation amount estimation based on the cumulative time is suitable when the degradation of a battery progresses, such as when gas is generated at the time of storage of the battery. On the other hand, the degradation amount estimation based on the cumulative electric power amount is suitable when the cycle of process, such as charge and discharge process, is repeated so that the deterioration of the battery, such as the volume change of the active material, is remarkable.

It should be noted that the data of the cumulative time or the cumulative electric power amount is assumed to be stored beforehand. The cumulative electric power amount may be replaced by the amount of operation of an apparatus, for example, the travel distance if the apparatus is a vehicle.

(Third Method)

The third method is a method in which the reaction resistance component and the diffusion resistance component are estimated by previously stored data of the charge amount and the diffusion resistance of each of the active materials, or by data of the reaction resistance and the charge amount, and then, the residual is set as the ohmic resistance component. The third method is a method which is different from the first and the second methods in that, in the analysis of the charge and discharge curve, regression calculation is performed with reference to an active material reaction resistance-charge amount curve, a diffusion resistance-charge amount curve, or a battery internal resistance-charge amount curve, to estimate the values of the reaction resistance and the diffusion resistance. By using the fact that the resistance component of the active material has dependence on the charge amount, that is, SOC, and that the tendency of the dependence is not changed by the deterioration, the composition of the internal resistance is estimated from the tendency of the internal resistance-charge amount curve of the battery.

It is necessary that the active material reaction resistance-charge amount curve, and the diffusion resistance-charge amount curve are measured beforehand. Further, the manner of change of the deterioration is also dependent on the configuration of the battery, and hence, it is necessary that the manner of change of the deterioration is measured beforehand. For example, it is considered that, when a resistive surface film is formed, the resistance is uniformly increased by a constant value according to the formation of the film, and that, when the active material is decreased, the resistance is uniformly increased by n times according to the decrease.

The third method is suitable for the case where there is a significant change in the reaction resistance-charge amount curve, so that the dependence of the charge amount on the reaction resistance in the battery is clearly recognized.

(Fourth Method)

The fourth method is a method in which regression calculation is performed by using diffusion resistance-charge amount data, reaction resistance-charge amount data, and ohmic resistance-charge amount data of each of the active materials held beforehand, and thereby, the reaction resistance component, the ohmic resistance component, and the diffusion resistance component are estimated. In the third method, the diffusion resistance-charge amount data and the reaction resistance-charge amount data are used. However, the fourth method is characterized in that the ohmic resistance-charge amount data is further used. The fourth method is effective when the ohmic resistance-charge amount data is characterized by its dependence on the active material, for example, when the electron conductivity of the active material is largely changed by charging and discharging.

The deterioration progress calculator 27 calculates the deterioration progress of the storage battery 1 for each predetermined performance (performance index). The deterioration progress of the storage battery 1 is different for each performance. For example, even when the electric power, which can be outputted within a predetermined period, is significantly lowered, there may be a case where the deterioration of the battery capacity is small. Therefore, when the deterioration progress is obtained, it is necessary to determine which of the performance indexes is used as the basis to obtain the deterioration progress.

Which of the performance indexes is used as the basis to calculate the deterioration progress may be determine according to the application of the storage battery 1. For example, when a current is desired to flow instantaneously, it is preferable that the resistance is not increased due to deterioration, and hence, it is considered to use the resistance as the performance index. The deterioration progress calculator 27 may acquire information related to the application of the storage battery 1, to calculate the deterioration progress related to the performance index corresponding to the application of the storage battery 1. For example, when the deterioration progress calculator 27 is provided with a table in which the application of the storage battery 1 is associated with the performance index, the deterioration progress calculator 27 can calculate the deterioration progress related to the performance index corresponding to the application of the storage battery 1. The application of the storage battery 1 may be acquired from the storage battery 1, the user, or other system via acquirer (not illustrated).

Further, the next application of the collected storage battery 1 back may be unknown. In order to cope with such case, the deterioration progress calculator 27 may obtain the deterioration progress of each of a plurality of performance indexes. Further, the deterioration progress calculator 27 may select the deterioration progress satisfying conditions from the calculated deterioration progress, and may use the selected deterioration progress as the deterioration progress of the storage battery 1. For example, among the deterioration progress respectively corresponding to the performance indexes, the largest deterioration progress may be used as the deterioration progress of the storage battery 1.

It should be noted that, when the performance index is not specified, the deterioration progress calculator 27 may acquire information of the application of the storage battery 1, and the like, from the storage battery 1, other system, or the like, to determine the performance index of the deterioration progress to be calculated.

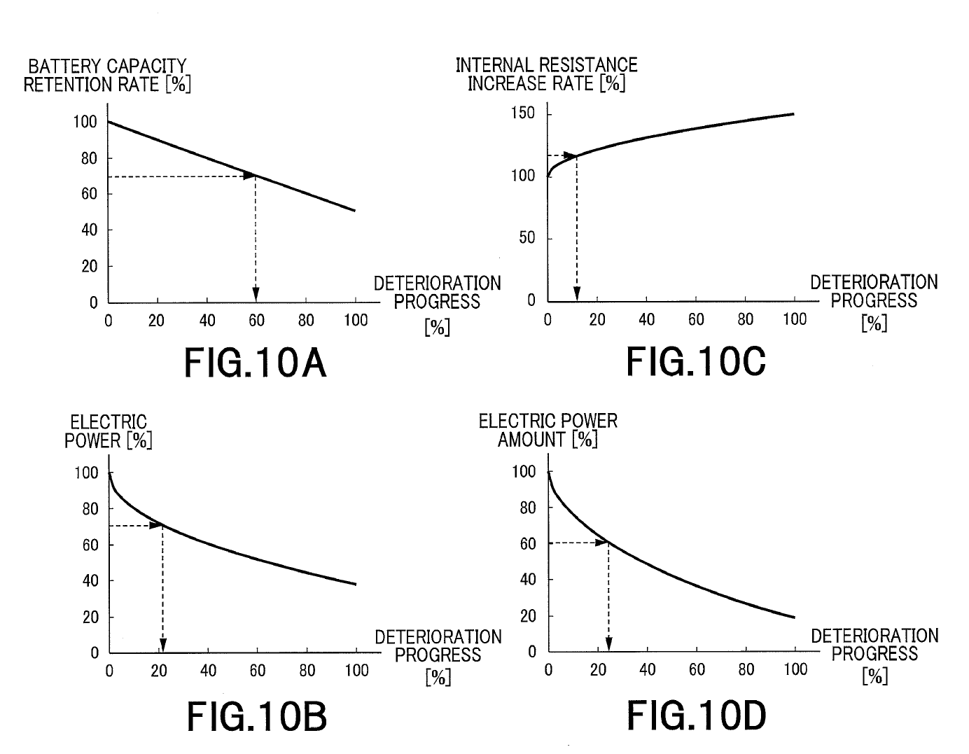

FIGS. 10A to 10D are views for explaining the progress of deterioration of each performance index. Each of the graphs of FIG. 10 is a graph (calculation function) to calculate the deterioration progress of each of the performance indexes in the general storage battery 1.

Here, a graph to calculate a deterioration progress is referred to as a deterioration progress calculation graph. FIG. 10 illustrates an example in which each of the battery capacity retention rate, the internal resistance increase rate, the electric power, and the electric power amount is set as the performance index. In FIG. 10, the vertical axis represents the value of each of the performance indexes. The value of each of the performance indexes is represented by a relative value based on the initial value of each of the performance indexes. In FIG. 10, the horizontal axis represents the deterioration progress of the battery. The deterioration progress is represented by a relative value based on a use limit value (life) of a general battery corresponding to each of the performance indexes. It should be noted that the use limit value of the storage battery 1 may be determined freely on the basis of the applications, specifications, and the like, of the storage battery 1.

As illustrated in FIG. 10, the deterioration progress calculator 27 calculates the deterioration progress for each of the performance indexes, with reference to each of the deterioration progress calculation graphs and on the basis of the value of each of the performance indexes. For example, it is assumed to be calculated as follows, at the present time, the battery capacity retention rate is 70%, the internal resistance increase rate is 120%, the electric power is 70%, and the electric power amount is 60%. The deterioration progress calculator 27 acquires these values. Then, with reference to the deterioration progress calculation graphs illustrated in FIG. 10, the deterioration progress calculator 27 acquires the horizontal axis values of each of the graphs in the state where the values of each of the performance indexes are represented by the vertical axis as illustrated by the dotted line arrow in FIG. 10. Then, the deterioration progress calculator 27 calculates the deterioration progress of each of the present performance indexes which are calculated so that the battery capacity is 60%, the internal resistance is 16%, the electric power is 23%, and the electric power amount is 25%. It should be noted that, when the deterioration progress calculator 27 sets the deterioration progress of the index having the largest deterioration as the deterioration progress of the storage battery 1, the deterioration progress calculator 27 selects the deterioration progress of the battery capacity 1, which degree has the largest value, and sets the selected deterioration progress of the storage battery 1 to 60%.

The deterioration progress calculation graph or the deterioration progress calculation function may be retained by the deterioration progress calculator 27, or may be stored in the storage 24.

In order to calculate the deterioration progress, the deterioration progress calculator 27 acquires or calculates the required value of the predetermined performance index. For example, when the deterioration progress calculator 27 sets the battery capacity retention rate as the performance index, the deterioration progress calculator 27 calculates the value of the performance index in such a manner that the estimated value of the battery capacity after lease or rental, which value is calculated by the active material amount calculator 22, is divided by the estimated value of the battery capacity before lease or rental. For example, when the deterioration progress calculator 27 sets the internal resistance increase rate as the performance index, the deterioration progress calculator 27 calculates the value of the performance index in such a manner that the estimated value of the internal resistance after lease or rental, which value is calculated by the active material amount calculator 252 or the internal resistance corrector 26, is divided by the estimated value of the internal resistance before lease or rental.

Further, when the deterioration progress calculator 27 sets the electric power or the electric power amount as the performance index, the deterioration progress calculator 27 can obtain the value of the performance index by using calculation expression described below, or the like. Here, c denotes a predetermined constant.

(Electric Power)

Electric power=current×open-circuit voltage−c×internal resistance×(current)²

(Electric Power Amount)

Electric power amount=battery capacity retention rate×{open-circuit voltage−c×internal resistance×(current)²}

As the open-circuit voltage required for obtain the electric power and the electric power amount, the estimated value calculated by the open-circuit voltage calculator 253 may be used. As internal resistance, the estimated value calculated by the active material amount calculator 252 or the internal resistance corrector 26 may be used. However, when the estimated value calculated by the internal resistance corrector 26 is used, the accuracy can be improved. The current may be acquired from the measurement data of the measurer 22. It should be noted that the deterioration progress calculator 27 may receive the value of each of the performance indexes, the value of the parameter required for calculation, or the like, via the other component, such as the storage 24.

Further, the above-described electric power amount may be set as the electric power amount which can be actually outputted. The electric power amount, which can be actually outputted, can be calculated on the basis of the charge amount-OCV curve, the dischargeable electrical power and the internal resistance.

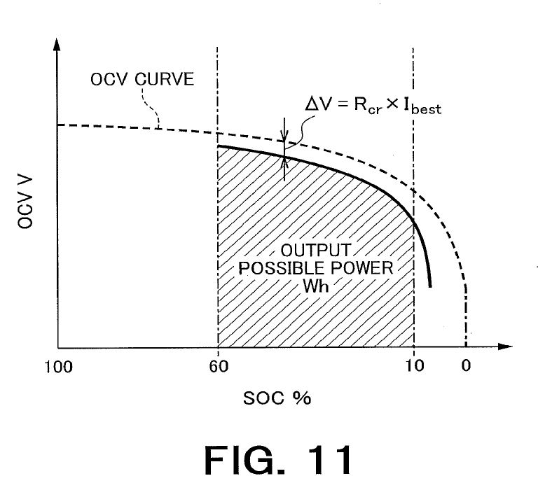

The method to obtain the electric power amount (Wh), which can be outputted, will be described. FIG. 11 is a view which explains the calculation of the electric power amount (Wh) that can be inputted and outputted. The internal resistance after correction at the present temperature of the storage battery 1 is set as Rcr. The present SOC of the storage battery 1, which is estimated by the SOC estimator 23, is assumed to be 60%. Further, the present battery capacity, which is calculated by the battery characteristic estimator 25, is assumed to be 10 Ah.

First, the deterioration progress calculator 27 calculates the amount of electricity (Ah), which can be charged and discharged at present. Since the battery capacity at present is 10 Ah, and since the SOC is 60%, the unit cell stores the electric power amount of 6 Ah at present. Therefore, the amount of electricity (Ah), which can be charged and discharged at present, becomes such that the charge (input) amount is 4 Ah, and such that the discharge (output) amount is 6 Ah. However, in many cases, the range of SOC of the storage battery 1, which can be actually used, is set to about 10% to about 90% for the safety or the operation design. Hence, the range of SOC is set to 10% to 90% in this deterioration description. This is because the charge amount of 1 Ah as last 10% cannot be used in both the charging and discharging. Therefore, the amount of electricity (Ah) which can be practically charged becomes 3 Ah obtained by subtracting the 1 Ah from 4 Ah, and the amount of electricity (Ah) which can be practically discharged becomes 5 Ah obtained by subtracting the 1 Ah from 6 Ah.

Next, the current value Ibest, which is correspond to the calculated amount of electricity (Ah), is determined. the current value Ibest is determined for fully using the amount of electricity without waste which can be charged and discharged during a fixed period of time t. It should be noted that, when the design current value is smaller than the design current value Imax of the storage battery 1, Ibest is set to Imax. In the example of FIG. 11, the case is considered where the discharge is performed during 30 minutes from the storage battery 1. For discharging (outputting) the amount of electricity 5 Ah which can be practically discharged in 30 minutes, the current value Ibest becomes 10 A since Ibest×0.5 h=5 Ah.

Then, the deterioration progress calculator 27 calculates the voltage drop ΔV at the time of discharge (output) by using the corrected internal resistance Rcr and the current value Ibest. The voltage drop ΔV at the time of discharge can be obtained by ΔV=Rcr×Ibest.

Then, on the basis of the voltage drop ΔV and the SOC-OCV curve, the deterioration progress calculator 27 calculates the amount of electric power (Wh) which can be actually inputted and outputted by the unit cell in a fixed period of time t. The amount of electric power (Wh), which can be actually inputted and outputted, is represented by the hatched region in FIG. 11. It should be noted that, when amount of electricity 5 Ah is discharged, the remaining amount of electricity is 1 Ah, and hence, the SOC is 10%. In this way, the deterioration progress calculator 27 may calculate inputtable amount or outputtable amount of electric power (Wh).

The deterioration progress calculated by the deterioration progress calculator 27 is notified to the display device 3. Further, the notified content is not limited to the deterioration progress of the unit cell, and may include information about the deterioration progress of each of the battery modules and each of the battery packs, the internal state of the storage battery 1, and the like.

As described above, according to the first embodiment, the present deterioration progress can be estimated from estimated values, and the like, of the storage battery 1 before and after the lease or rental. Thereby, it is possible to evaluate the present value of the storage battery 1. It should be noted that the lease or rental fee may be calculated on the basis of the present value of the storage battery 1.

### Second Embodiment

In the first embodiment, the deterioration progress calculator 27 calculates the deterioration progress by using the deterioration progress calculation graph based on the general progress of deterioration. However, the deterioration progress of the storage battery 1 is increased or decreased due to the difference of the use frequency, the use environment, the load, and the like. Therefore, in the second embodiment, the deterioration progress calculation graph is updated according to the state of the storage battery 1, and the like. Thereby, the accuracy of the deterioration progress can be improved as compared with the first embodiment.

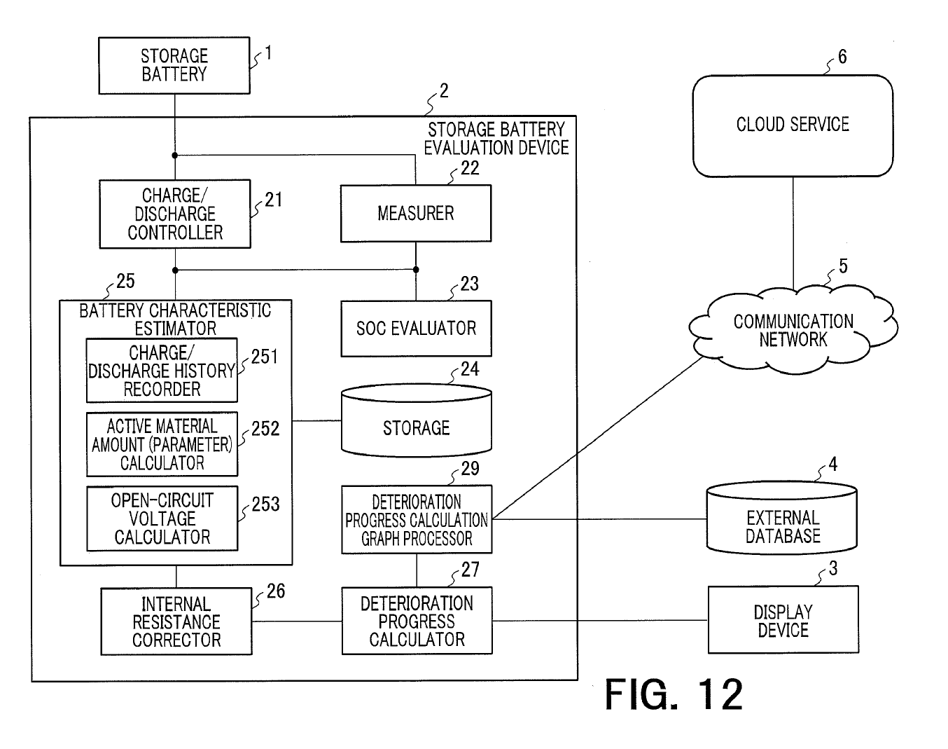

FIG. 12 is a block diagram illustrating an example of a schematic configuration of a storage battery system provided with the storage battery evaluation device 2 according to the second embodiment. The second embodiment is different from the first embodiment in that the storage battery evaluation device 2 is provided with a deterioration progress calculation graph processor 28. Further, the second embodiment is different from the first embodiment in which the storage battery system is further provided with an external database 4 connected to the deterioration progress calculation graph processor 28. Portions that are the same as those of the first embodiment are omitted.

The storage battery evaluation device 2 and the external database 4 are connected to each other by a wired or wireless communication of electric signals, so that data can be transferred between the storage battery evaluation device 2 and the external database 4. Further, the external database 4 may be connected to the storage battery evaluation device 2 via an external communication network 5. For example, the external database 4, as a cloud service 6, or the like, may transmit (download) necessary information to the storage battery evaluation device 2. The storage battery evaluation device 2 may transmit (upload) information of the calculated deterioration progress, and the like, to the external database 4.

The deterioration progress calculation graph processor 28 acquires, from the external database 4, a new deterioration progress calculation graph or values of parameters to update the deterioration progress calculation graph. The kind and number of parameters are not particularly limited. Further, the shape of the graph may be changed. For example, a graph of the primary rule may be changed to a graph of the route rule. On the contrary, a graph of the route rule may be changed to a graph of the primary rule. Also, the shape of the change graph is not limited in particular.

The deterioration progress calculation graph processor 28 may periodically acquire a new deterioration progress calculation graph, and the like. Further, on the basis of measurement data, battery characteristics, internal state parameters, values of performance indexes, and the like, the deterioration progress calculation graph processor 28 may determine whether to acquire a new deterioration progress calculation graph, and the like. Further, the database 4 may periodically transmit a new deterioration progress calculation graph, and the like.

For example, the deterioration progress calculation graph about the battery capacity retention rate illustrated in FIG. 10(A) is a deterioration progress calculation graph of a general storage battery 1. However, there may be a preferable case where another deterioration progress calculation graph different from the deterioration progress calculation graph illustrated in FIG. 10(A) is applied according to installed environment, use conditions, and the like, of the storage battery 1. Therefore, the deterioration progress calculation graph processor 28 may acquire a deterioration progress calculation graph on the basis of predetermined conditions. For example, when the estimated value of the amount of active material of the positive electrode terminal or the negative electrode terminal, or the like, which value is calculated by the active material amount calculator 252, is less than a threshold, the active material amount calculator 252 may determine that the deterioration progress calculation graph of the general storage battery 1 is not suitable, and acquire another deterioration progress calculation graph. The predetermined conditions and the threshold are not limited in particular.

It is assumed that information about the deterioration progress of each of various storage batteries 1 is stored in the external database 4. For example, deterioration progress calculation graphs associated with the information on the storage battery 1, such as the kind of storage battery 1, the use conditions, the use period, and the using history, are stored in the external database 4. From the deterioration progress calculation graph processor 28, the external database 4 may acquire each of the battery states of the present storage battery 1, such as the battery characteristics, the internal state parameters, the use period, the discharge capacity retention rate, the present voltage, the present temperature, or the like, to transmit a deterioration progress calculation graph corresponding to the states, and the like, of the battery 1, on the basis of the acquired information.

The external database 4 may transmit information other than the information of the deterioration progress calculation graph to the storage battery evaluation device 2. For example, the external database 4 may determine the use of the storage battery 1 on the basis of the measurement data of the storage battery 1, to transmit the determined use of the storage battery 1 to the storage battery evaluation device 2. The deterioration progress calculator 27 may determine the performance index on the basis of the use of the storage battery 1.

The deterioration progress calculation graph processor 28 updates the deterioration progress calculation graph of each of the performance indexes of the storage battery 1 on the basis of a new deterioration progress calculation graph or parameters. For example, in the deterioration progress calculation graph illustrated in FIG. 10, it is assumed that the deterioration progress calculation graph of the battery capacity retention rate is updated. Then, it is necessary to update the deterioration progress calculation graph of each of the other performance indexes dependent on the battery capacity retention rate. For example, it is assumed that the deterioration progress calculation graph of the electric power is the same as the calculation expression of the electric power described above, and that the deterioration progress calculation graph of the electric power amount is the same as the calculation expression of the electric power amount described above. In this case, when the deterioration progress calculation graph of the battery capacity retention rate is updated, it is necessary to update the deterioration progress calculation graph of the electric power, and when the internal resistance increase rate is updated, it is necessary to update each of the deterioration progress calculation graph of the electric power and the deterioration progress calculation graph of the electric power amount.

The acquisition process and update process of the deterioration progress calculation graph may be performed before the deterioration progress is calculated, and the time when the acquisition process and update process are not limited in particular.

The deterioration progress calculator 27 calculates a deterioration progress on the basis of the deterioration progress calculation graph updated by the deterioration progress calculation graph processor 28. The calculation of the deterioration progress is performed similarly to the first embodiment except that the deterioration progress calculation graph is updated. It should be noted that the deterioration progress calculator 27 may output the deterioration progress to the external database 4.

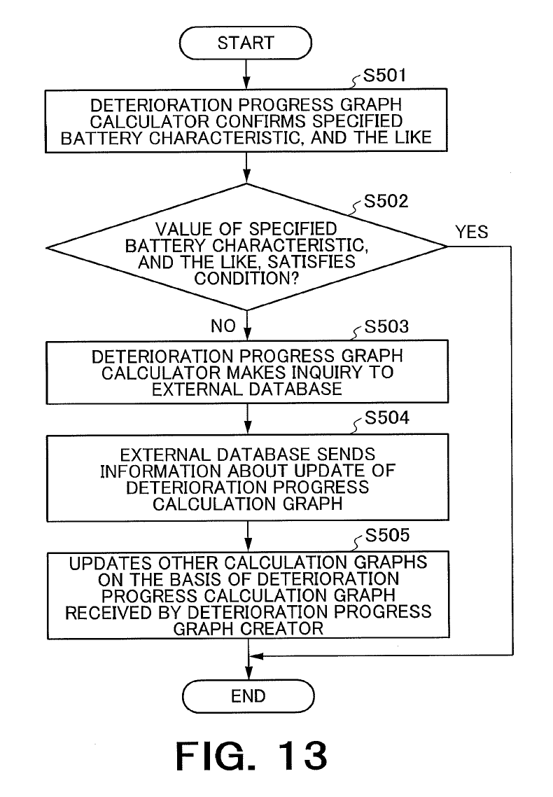

FIG. 13 is a view illustrating a flowchart which illustrates the process flow of the deterioration progress calculation graph processor 28. The flowchart may be performed at predetermined time. The flowchart may also be performed when the deterioration progress calculation graph processor 28 receives the measurement data, the estimated value, and the like.

The deterioration progress calculation graph processor 28 confirms the values, such as the specified battery characteristics, and the like (S501). When the values, such as the battery characteristics, satisfy predetermined conditions (YES in S502), the deterioration progress calculation graph processor 28 terminates the flow. When the values, such as the battery characteristics, do not satisfy predetermined conditions (NO in S502), the deterioration progress calculation graph processor 28 performs inquiry to the external database 4 (S503). It should be noted that the deterioration progress calculation graph processor 28 may unconditionally perform inquiry to the external database 4. In this case, the processes of S501 and 502 are omitted.

The external database 4 acquires information on the storage battery 1 from the deterioration progress calculation graph processor 28. On the basis of the information, the external database 4 transmits the information about the update of the deterioration progress calculation graph to the deterioration progress calculation graph processor 28 (S504). On the basis of the transmitted information, the deterioration progress calculation graph processor 28 updates the deterioration progress calculation graph according to the information (S505). Further, the deterioration progress calculation graph processor 28 also updates the other deterioration progress calculation graphs corresponding to the updated deterioration progress calculation graph. The above is the flow of the outline processing of the deterioration progress calculation graph processor 28.

As described above, according to the second embodiment, the general calculation graph of the deterioration progress is not used as it is, but is updated. At this time, on the basis of the information on the storage battery 1, the calculation graph of the deterioration progress is updated to correspond to the states of the storage battery 1, and the like, and hence, the deterioration progress can be accurately estimated. Thereby, the deterioration progress and the worth of the storage battery 1 can be calculated more accurately than the first embodiment.

Further, each process in the embodiments described above can be realized by software (program). Therefore, the storage battery evaluation device 2 in the embodiments described above can be realized, for example, in such a manner that a general-purpose computer device is uses as basic hardware, and that a processor mounted in the computer device is made to execute programs by the computer device.

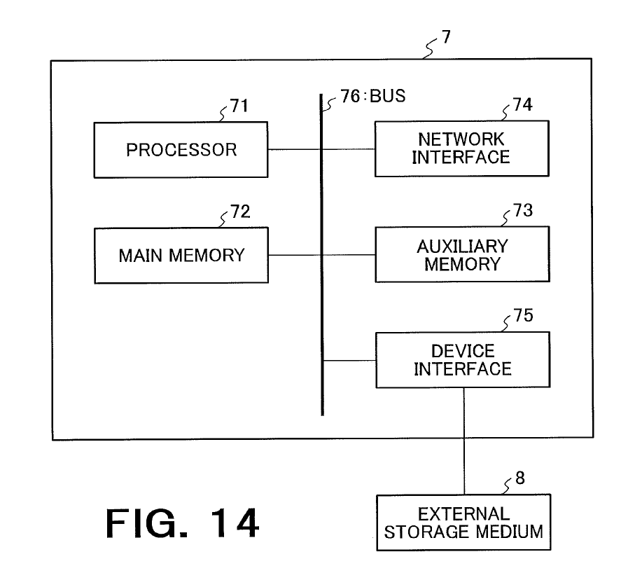

FIG. 14 is a block diagram illustrating an example of a hardware configuration in an embodiment of the present invention. The storage battery evaluation device 2 includes a processor 71, a main memory 72, an auxiliary memory 73, a network interface 74, and a device interface 75, which are connected to each other via a bus 76 to realize a computer device 7.

The processor 71 reads the program from the auxiliary memory 73 and expands the program in the main memory 72 and executes it. Thereby, it is possible to realize the functions of the charge/discharge controller 21, the measurer 22, the SOC estimator 23, the battery characteristic estimator 25, the internal resistance corrector 26, the deterioration progress calculator 27, and the deterioration progress calculation graph processor 28.

The processor 71 is an electronic circuit including a control device of a computer and a calculation device. As the processor 71, it is possible to use, for example, a general-purpose processor, a central processing unit (CPU), a microprocessor, a digital signal processor (DSP), a controller, a microcontroller, a state machine, an application-specific integrated circuit, a field programmable gate array (FPGA), a programmable logic device (PLD), and a combination of these.

The storage battery evaluation device 2 in the present embodiment may be realized in such a manner that programs executed by the respective devices are installed in the computer device 7 in advance, or that the programs are stored in a storage medium, such as CD-ROM, or are distributes via a network, to be properly installed in the computer device 7.

The main memory 72 is a memory device temporarily storing commands, various data, and the like, executed by the processor 71, and may be a volatile memory, such as DRAM, or a nonvolatile memory, such as MRAM. The auxiliary memory 73 is a storage device permanently storing the programs, data, and the like, and is, for example, a flash memory, and the like.

The network interface 74 is an interface connected to a communication network by wire or wirelessly. Via the network interface 74, the output results may be transmitted to other communication devices. Here, only one network interface 74 is illustrated, but a plurality of network interfaces 74 may be mounted. Via the network interface 74, the display device 3, the external database 4, and the like, may be connected to each other.

The device interface 75 is an interface, such as a USB, connected to an external storage medium 8 storing the output results, and the like. The external storage medium 8 is an arbitrary storage medium, such as HDD, CD-R, CD-RW, DVD-RAM, DVD-R, and SAN (Storage area network). Via the device interface 75, the storage battery 1, the display device 3, and the external database 4 are connected to each other.

The computer device 7 may be configured by dedicated hardware, such as a semiconductor integrated circuit to which the processor 71, and the like, is mounted. The dedicated hardware may be configured by a combination of storage devices, such as RAM and ROM. The computer device 7 may be incorporated in the storage battery 1.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A storage battery evaluation device comprising
a processor configured to execute a program to provide at least:
a battery characteristic estimator configured to estimate a battery characteristic including at least one of battery capacity, internal resistance, and open-circuit voltage of a secondary battery on the basis of data of voltage and current of the secondary battery, the data being measured at the time of charging or discharging of the secondary battery; and
a deterioration progress calculator configured to calculate a deterioration progress representing the progress of deterioration of the secondary battery, on the basis of a value related to a performance index of the secondary battery, the value being calculated on the basis of the battery characteristic.

2. The storage battery evaluation device according to claim 1, wherein:
the battery characteristic estimator calculates initial charge amount and mass of each of a positive electrode and a negative electrode of the secondary battery on the basis of the data of voltage and current of the secondary battery, and calculates the open-circuit voltage on the basis of the calculated initial charge amount and mass; and
the deterioration progress calculator calculates the deterioration progress on the basis of electric power or electric power amount of the secondary battery, the electric power or electric power amount being calculated on the basis of at least the open-circuit voltage calculated by the battery characteristic estimator.

3. The storage battery evaluation device according to claim 1, wherein
the deterioration progress calculator calculates a deterioration progress related to each of a plurality of performance indexes, at least one of the indexes being the electric power or the electric power amount of the secondary battery, and outputs the deterioration progress satisfying a condition as the deterioration progress of the secondary battery.

4. The storage battery evaluation device according to claim 1, wherein
the deterioration progress calculator acquires information related to application of the secondary battery, and calculates a deterioration progress related to the performance index corresponding to the application of the secondary battery.

5. The storage battery evaluation device according to claim 1, wherein:
the processor is configured to execute the program to further provide an internal resistance corrector configured to calculate internal resistance at a predetermined reference temperature on the basis of data of temperature of the secondary battery, and on the basis of the internal resistance estimated by the battery characteristic estimator; and
the deterioration progress calculator calculates the electric power or the electric power amount of the secondary battery at the reference temperature on the basis of the internal resistance at the reference temperature.

6. The storage battery evaluation device according to claim 1, wherein:
the processor is configured to execute the program to further provide a deterioration progress calculation graph processor configured to update a calculation function used to calculate the deterioration progress on the basis of a newly acquired calculation function or a new parameter; and
the deterioration progress calculator calculates the deterioration progress on the basis of the calculation function updated by the deterioration progress calculation graph processor.

7. The storage battery evaluation device according to claim 1, wherein:
the battery characteristic estimator calculates the initial charge amount and mass of each of a positive electrode and a negative electrode of the secondary battery on the basis of data of temperature, voltage and current of the secondary battery, and calculates a function representing the relationship between the open-circuit voltage of the secondary battery and the charging state or the charged charge amount of the secondary battery on the basis of the calculated initial charge amount and mass; and
the deterioration progress calculator calculates inputtable amount or outputtable amount of electric power of the secondary battery on the basis of the internal resistance and the function estimated by the battery characteristic estimator, and calculates a deterioration progress related to the inputtable amount or outputtable amount of electric power of the secondary battery.

8. A storage battery comprising, as a secondary battery, the storage battery evaluation device according to claim 1.

9. A storage battery evaluation method executed by a computer, the method comprising:
estimating a battery characteristic including at least one of battery capacity, internal resistance, and open-circuit voltage of a secondary battery on the basis of data of voltage and current of the secondary battery, the data being measured at the time of charging or discharging of the secondary battery; and
calculating a deterioration progress representing the progress of deterioration of the secondary battery, on the basis of a value related to a performance index of the secondary battery, the value being calculated on the basis of the battery characteristic.

10. A non-transitory computer readable medium having a computer program stored therein which causes a computer when executed by the computer, to perform processes comprising:
estimating a battery characteristic including at least one of battery capacity, internal resistance, and open-circuit voltage of a secondary battery on the basis of data of voltage and current of the secondary battery, the data being measured at the time of charging or discharging of the secondary battery; and
calculating a deterioration progress representing the progress of deterioration of the secondary battery, on the basis of a value related to a performance index of the secondary battery, the value being calculated on the basis of the battery characteristic.
